(19) United States
(12) Patent Application Publication
(10) Pub. No.: US 2026/0110729 A1
(43) Pub. Date: Apr. 23, 2026

(54) TESTING DEVICE AND TESTING METHOD FOR ENERGY DISSIPATION DEVICE IN POWER TRANSMISSION SYSTEM

(71) Applicant: STATE GRID JIANGSU ELECTRIC POWER CO., LTD RESEARCH INSTITUTE, Nanjing (CN)

(72) Inventors: Ke ZHAO, Nanjing (CN); Jinggang YANG, Nanjing (CN); Yang XU, Nanjing (CN); Hongtao LI, Nanjing (CN); Bo QIAN, Nanjing (CN); Qiang HUANG, Nanjing (CN); Zhaohui ZHANG, Nanjing (CN); Rong SUN, Nanjing (CN); Songtao CHEN, Nanjing (CN); Jiangang XU, Nanjing (CN); Tianxi XIE, Nanjing (CN); Jianjun LIU, Nanjing (CN); Yang CHEN, Nanjing (CN)

(73) Assignee: STATE GRID JIANGSU ELECTRIC POWER CO., LTD RESEARCH INSTITUTE, Nanjing (CN)

(21) Appl. No.: 19/483,256

(22) PCT Filed: Aug. 30, 2023
(86) PCT No.: PCT/CN2023/115686

§ 371 Date: Nov. 11, 2025

(30) Foreign Application Priority Data
Apr. 10, 2023 (CN) 202310370631.1

(51) Int. Cl. G01R 31/28; G01R 15/20

(52) U.S. Cl. CPC G01R 31/2827; G01R 15/202; G01R 31/2837; G01R 31/2839

(57) ABSTRACT

A testing device and a testing method for an energy dissipation device in a power transmission system are provided. The testing device includes a high-capacity DC power supply, a first energy dissipation unit, a second energy dissipation unit, a third energy dissipation unit, a communication module, and a control unit. The high-capacity DC power supply is connected to high-voltage terminals of the first energy dissipation unit, the second energy dissipation unit, and the third energy dissipation unit. The first energy dissipation unit, the second energy dissipation unit, and the third energy dissipation unit are connected to each other in parallel. The testing device enables testing of all parallel-connected energy dissipation units inside the energy dissipation device through just a single wiring operation, and enables precise measurement of the DC reference voltage and the leakage current of each resistor module in each energy dissipation unit.

### CROSS REFERENCE TO THE RELATED APPLICATIONS

This application is the national phase entry of International Application No. PCT/CN2023/115686, filed on Aug. 30, 2023, which is based upon and claims priority to Chinese Patent Application No. 202310370631.1, filed on Apr. 10, 2023, the entire contents of which are incorporated herein by reference.

### TECHNICAL FIELD

This application relates to the field of testing technology for an energy dissipation device in a power transmission system, and in particular, to a testing device and a testing method for an energy dissipation device in a power transmission system.

### BACKGROUND

Energy dissipation devices are important for enabling AC-side fault ride-through in a flexible DC transmission system. An energy dissipation device is typically formed of hundreds of resistor modules connected in parallel. Each resistor module is made of a zinc oxide material, and is a nonlinear resistor.

Currently, in a high-voltage test of a plurality of energy dissipation units connected in parallel, the test can only be performed on individual energy dissipation units, thereby resulting in a heavy workload of testing personnel, and being time-consuming and inefficient. To reduce the workload, an existing method is to directly measure a total DC reference voltage and a total leakage current of all energy dissipation units without disconnecting wires. However, this method is unable to precisely measure the DC reference voltage and the leakage current of each individual energy dissipation unit, and the testing results lack reliability. In the high-voltage test of an energy dissipation device, it becomes a pressing challenge to precisely measure the DC reference voltage and the leakage current of each resistor module without disassembling the main body of the energy dissipation device that contains a large number of energy dissipation units connected in parallel. Therefore, it is necessary to design a testing device and a testing method for an energy dissipation device in a power transmission system.

### SUMMARY

A main objective of this application is to solve the problem that, in a high-voltage test of a plurality of energy dissipation units connected in parallel currently, the test can only be performed on individual energy dissipation units, which results in a heavy workload of testing personnel and is time-consuming and inefficient. This application provides a testing device and a testing method for an energy dissipation device in a power transmission system, enables testing of all parallel-connected energy dissipation units inside the energy dissipation device through just a single wiring operation, and enables precise measurement of the DC reference voltage and the leakage current of each resistor module in each energy dissipation unit.

To achieve the above objective, this application puts forward the following technical solutions:

A testing device for an energy dissipation device in a power transmission system is provided. The testing device includes a high-capacity DC power supply 5, a first energy dissipation unit 1, a second energy dissipation unit 2, a third energy dissipation unit 3, a communication module 4, and a control unit 6. The high-capacity DC power supply 5 is connected to high-voltage terminals of the first energy dissipation unit 1, the second energy dissipation unit 2, and the third energy dissipation unit 3. The first energy dissipation unit 1, the second energy dissipation unit 2, and the third energy dissipation unit 3 are connected to each other in parallel. Low-voltage terminals of the first energy dissipation unit 1, the second energy dissipation unit 2, and the third energy dissipation unit 3 are all grounded. The communication module 4 is disposed within 10 meters of the first energy dissipation unit 1, the second energy dissipation unit 2, and the third energy dissipation unit 3. The communication module 4 is configured to coordinate with the control unit 6 to form a local area network near the first energy dissipation unit 1, the second energy dissipation unit 2, and the third energy dissipation unit 3 for measurement and control communication, and to perform control and data reception inside the first energy dissipation unit 1, the second energy dissipation unit 2, and the third energy dissipation unit 3.

In the testing device for an energy dissipation device in a power transmission system, the first energy dissipation unit 1 includes a first resistor module 101 and a second resistor module 103. A high-voltage terminal of the first resistor module 101 is connected to the high-capacity DC power supply 5. A low-voltage terminal of the first resistor module 101 is connected to a high-voltage terminal of the second resistor module 103. A measurement integration module 102 is mounted on outer walls of bottom surfaces of the first resistor module 101 and the second resistor module 103. A ground terminal of the second resistor module 103 is grounded through a post insulator 105. An impedance adjustment module 104 is connected in series between the second resistor module 103 and the post insulator 105.

In the testing device for an energy dissipation device in a power transmission system, the number of measurement integration modules 102 is two. Each measurement integration module 102 is provided with an opening, and is directly fitted onto outer walls of bottom surfaces of the first resistor module 101 and the second resistor module 103 separately. The measurement integration module 102 is made of a DC current sensor and a DC voltage sensor that are Hall-effect-based, and is configured to measure current and voltage in real time.

In the testing device for an energy dissipation device in a power transmission system, the impedance adjustment module 104 is configured to automatically adjust a grounding impedance of the second resistor module 103 and make a leakage current of the second resistor module 103 not greater than 2 mA. A precision measurement resistor, a filtering voltage divider, an AD sampler, a high-voltage variable-impedance device, a fine-tuning mechanism, a DSP, and a wireless communicator are disposed inside the impedance adjustment module. The precision measurement resistor is configured to measure voltage and output voltage data to the filtering voltage divider. The filtering voltage divider is configured to filter and scale a voltage signal to obtain a voltage value and a leakage current value, and then output the values to the AD sampler. The AD sampler is configured to convert the voltage value and the leakage current value into digital values and output the digital values to the DSP. The DSP is configured to send a signal to the fine-tuning mechanism after calculation and comparison so that the fine-tuning mechanism adjusts a resistance value. The wireless communicator is configured to establish a wireless communication connection with a communication module.

In the testing device for an energy dissipation device in a power transmission system, the impedance adjustment module 104 and the measurement integration module 102 are wirelessly connected to the control unit 6 by the communication module 4 through wireless data communication. The communication module 4, the impedance adjustment module 104, and the measurement integration module 102 are all equipped with and powered by batteries, and a battery charge level is displayed in real time and wirelessly transmitted to the control unit 6.

In the testing device for an energy dissipation device in a power transmission system, the first resistor module 101 and the second resistor module 103 are both made of a resistor column, and the resistor column is made of a zinc oxide material.

In the testing device for an energy dissipation device in a power transmission system, internal structures of both the second energy dissipation unit 2 and the third energy dissipation unit 3 are identical to an internal structure of the first energy dissipation unit 1.

In the testing device for an energy dissipation device in a power transmission system, the number of the first energy dissipation units 1, the number of the second energy dissipation units 2, and the number of the third energy dissipation units 3 are plural. The plurality of first energy dissipation units 1, the plurality of second energy dissipation units 2, and the plurality of third energy dissipation units 3 are all connected in parallel to a high-capacity DC power supply 5.

A testing method applicable to the testing device for an energy dissipation device in a power transmission system is provided, including the following steps:
Step A: A voltage-rise test is performed, including the following specific steps:
Step A1: The control unit 6 controls, in real time, a voltage of the high-capacity DC power supply 5 to rise; meanwhile, the measurement integration module 102 monitors a DC voltage and a leakage current of each resistor module in the first energy dissipation unit 1, the second energy dissipation unit 2, and the third energy dissipation unit 3 in real time, and outputs the DC voltage and the leakage current to the control unit 6 in real time;
Step A2: In the case that the leakage current of a resistor module reaches 1 mA, a DC reference voltage of the resistor module is recorded;
Step A3: The control unit 6 continues to control the voltage of the high-capacity DC power supply 5 to rise slowly; meanwhile, the impedance adjustment modules 104 in the first energy dissipation unit 1, the second energy dissipation unit 2, and the third energy dissipation unit 3 begin to increase impedance, and ensure that the leakage current leaked to the post insulator 105 remains within 2 mA;
Step A4: The testing proceeds until the DC reference voltages of all resistor modules are measured, and then the voltage-rise test ends;
Step B: A voltage-drop test is performed, including the following specific steps:
Step B1: The control unit 6 controls, in real time, the voltage of the high-capacity DC power supply 5 to drop; meanwhile, the measurement integration module 102 monitors the DC voltage and the leakage current of each resistor module in the first energy dissipation unit 1, the second energy dissipation unit 2, and the third energy dissipation unit 3 in real time;
Step B2: The control unit 6 controls, through the communication module 4, the impedance adjustment module 104 to reduce impedance; in the case that the DC voltage of a resistor module reaches 0.75 times the DC reference voltage, the leakage current of the resistor module is recorded; and
Step B3: The control unit 6 continues to control the voltage of the high-capacity DC power supply 5 to drop slowly until the DC reference voltages of all resistor modules are measured, and then the voltage is further reduced to zero, so that the voltage drop process ends and the test is completed.

Compared with the prior art, this application achieves at least the following beneficial effects:

This application effectively enables testing of all parallel-connected energy dissipation units inside the energy dissipation device through just a single wiring operation, and enables precise measurement of the DC reference voltage and the leakage current of each resistor module in each energy dissipation unit. This application is suitable for DC testing for an energy dissipation device that contains a large number of parallel-connected energy dissipation units, and can perform an overall test for the energy dissipation device containing a plurality of energy dissipation units connected in parallel, thereby significantly reducing the test workload and ensuring reliability of test results.

### BRIEF DESCRIPTION OF THE DRAWINGS

FIG. 1 is an overall schematic structural diagram of this application;

FIG. 2 is a schematic diagram of a specific structure of an energy dissipation unit according to this application;

FIG. 3 is a schematic diagram of control logic according to this application;

FIG. 4 is a schematic diagram of working principles of an impedance adjustment module according to this application;

FIG. 5 is a schematic diagram of a voltage-rise testing process according to an embodiment of this application;

FIG. 6 is a schematic diagram of a voltage-drop testing process according to an embodiment of this application.

List of reference numerals: 1. first energy dissipation unit; 101. first resistor module; 102. measurement integration module; 103. second resistor module; 104. impedance adjustment module; 105. post insulator; 2. second energy dissipation unit; 3. third energy dissipation unit; 4. communication module; 5. high-capacity DC power supply; 6. control unit.

### DETAILED DESCRIPTION OF THE EMBODIMENTS

To make the technical means, creative features, objectives, and effects of this application more comprehensible, this application is further described below with reference to specific embodiments.

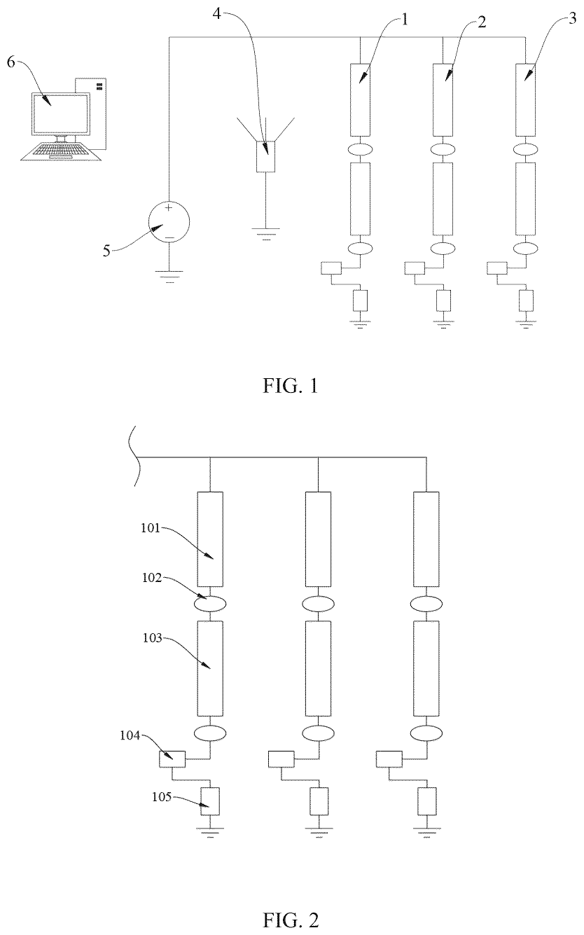

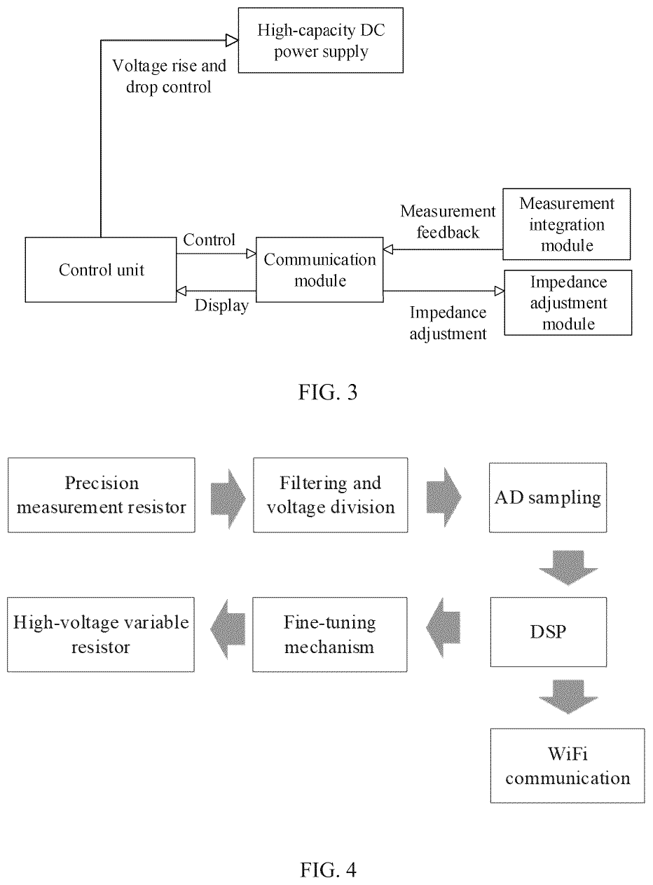

As shown in FIG. 1 to FIG. 3, a testing device and a testing method for an energy dissipation device in a power transmission system are provided. The testing device includes a high-capacity DC power supply 5, a first energy dissipation unit 1, a second energy dissipation unit 2, a third energy dissipation unit 3, a communication module 4, and a control unit 6. The high-capacity DC power supply 5 is connected to high-voltage terminals of the first energy dissipation unit 1, the second energy dissipation unit 2, and the third energy dissipation unit 3. The first energy dissipation unit 1, the second energy dissipation unit 2, and the third energy dissipation unit 3 are connected to each other in parallel. Low-voltage terminals of the first energy dissipation unit 1, the second energy dissipation unit 2, and the third energy dissipation unit 3 are all grounded. The communication module 4 is disposed within 10 meters of the first energy dissipation unit 1, the second energy dissipation unit 2, and the third energy dissipation unit 3. The communication module 4 is configured to coordinate with the control unit 6 to form a local area network near the first energy dissipation unit 1, the second energy dissipation unit 2, and the third energy dissipation unit 3 for measurement and control communication, and to perform control and data reception inside the first energy dissipation unit 1, the second energy dissipation unit 2, and the third energy dissipation unit 3. The communication module 4 enables the control unit 6 to be wirelessly connected to the first energy dissipation unit 1, the second energy dissipation unit 2, and the third energy dissipation unit 3 through wireless data communication.

Specifically, the first energy dissipation unit 1 includes a first resistor module 101 and a second resistor module 103. A high-voltage terminal of the first resistor module 101 is connected to the high-capacity DC power supply 5. A low-voltage terminal of the first resistor module 101 is connected to a high-voltage terminal of the second resistor module 103. A measurement integration module 102 is mounted on outer walls of bottom surfaces of the first resistor module 101 and the second resistor module 103. A ground terminal of the second resistor module 103 is grounded through a post insulator 105. An impedance adjustment module 104 is connected in series between the second resistor module 103 and the post insulator 105. The first resistor module 101 and the second resistor module 103 enable the first energy dissipation unit 1 to achieve the designed function of energy dissipation.

Specifically, the number of measurement integration modules 102 is two. Each measurement integration module 102 is provided with an opening, and is directly fitted onto outer walls of bottom surfaces of the first resistor module 101 and the second resistor module 103 separately. The measurement integration module 102 is made of a DC current sensor and a DC voltage sensor that are Hall-effect-based, and is configured to measure current and voltage in real time. The measurement integration module 102 can monitor the DC voltage and the leakage current of each resistor module in the first energy dissipation unit 1, the second energy dissipation unit 2, and the third energy dissipation unit 3 in real time, and output the DC voltage and the leakage current to the control unit 6 in real time.

As shown in FIG. 4, the impedance adjustment module 104 is configured to automatically adjust a grounding impedance of the second resistor module 103 and make a leakage current of the second resistor module 103 not greater than 2 mA. A precision measurement resistor, a filtering voltage divider, an AD sampler, a high-voltage variable-impedance device, a fine-tuning mechanism, a DSP, and a wireless communicator are disposed inside the impedance adjustment module. The precision measurement resistor is configured to measure voltage and output voltage data to the filtering voltage divider. The filtering voltage divider is configured to filter and scale a voltage signal to obtain a voltage value and a leakage current value, and then output the values to the AD sampler. The AD sampler is configured to convert the voltage value and the leakage current value into digital values and output the digital values to the DSP. The DSP is configured to send a signal to the fine-tuning mechanism after calculation and comparison so that the fine-tuning mechanism adjusts a resistance value. The wireless communicator is configured to establish a wireless communication connection with a communication module. The impedance adjustment module 104 ensures that the leakage current leaked to the post insulator 105 is kept within 2 mA.

If the measured voltage value exceeds a threshold, the DSP sends a signal to the fine-tuning mechanism. The fine-tuning mechanism increases the resistance of the high-voltage resistor by the same amount as the extent by which the voltage exceeds the threshold. If the measured voltage value is less than the threshold, the DSP sends a signal to the fine-tuning mechanism, and the fine-tuning mechanism decreases the resistance of the high-voltage resistor.

Specifically, the impedance adjustment module 104 and the measurement integration module 102 are wirelessly connected to the control unit 6 by the communication module 4 through wireless data communication. The communication module 4, the impedance adjustment module 104, and the measurement integration module 102 are all equipped with and powered by batteries, and a battery charge level is displayed in real time and wirelessly transmitted to the control unit 6. The fact that the communication module 4, the impedance adjustment module 104, and the measurement integration module 102 are all equipped with and powered by their own batteries allows the modules to operate independently of each other.

Specifically, the first resistor module 101 and the second resistor module 103 are both made of a resistor column, and the resistor column is made of a zinc oxide material. The fact that the first resistor module 101 and the second resistor module 103 are made of a zinc oxide material enables the modules to achieve the designed function of energy dissipation.

Specifically, internal structures of both the second energy dissipation unit 2 and the third energy dissipation unit 3 are identical to an internal structure of the first energy dissipation unit 1. By making the internal structures of the second energy dissipation unit 2 and the third energy dissipation unit 3 be identical to the internal structure of the first energy dissipation unit 1, this application enables each energy dissipation unit to play the same role.

Specifically, the number of the first energy dissipation units 1, the number of the second energy dissipation units 2, and the number of the third energy dissipation units 3 are plural. The plurality of first energy dissipation units 1, the plurality of second energy dissipation units 2, and the plurality of third energy dissipation units 3 are all connected in parallel to a high-capacity DC power supply 5. The fact that there are a plurality of first energy dissipation units 1, second energy dissipation units 2, and third energy dissipation units 3 allows the energy dissipation effect of the energy dissipation device to be adaptively adjustable and available.

Specifically, the method includes the following steps:
Step A: A voltage-rise test is performed, including the following specific steps:
Step A1: The control unit 6 controls, in real time, a voltage of the high-capacity DC power supply 5 to rise; meanwhile, the measurement integration module 102 monitors a DC voltage and a leakage current of each resistor module in the first energy dissipation unit 1, the second energy dissipation unit 2, and the third energy dissipation unit 3 in real time, and outputs the DC voltage and the leakage current to the control unit 6 in real time.

In this step, the leakage current is measured by the measurement integration module 102, and the DC reference voltage is calculated from the data obtained by the measurement integration module 102. For example, the DC reference voltage of the first resistor module 101 is equal to the voltage of the high-capacity DC power supply minus the voltage measured by the measurement integration module 102 at the bottom of the first resistor module 101; and the DC reference voltage of the second resistor module 103 is equal to the voltage measured by the measurement integration module 102 at the bottom of the first resistor module 101 minus the voltage measured by the measurement integration module 102 at the bottom of the second resistor module 103.
Step A2: In the case that the leakage current of a resistor module reaches 1 mA, a DC reference voltage of the resistor module is recorded.
Step A3: The control unit 6 continues to control the voltage of the high-capacity DC power supply 5 to rise slowly; meanwhile, the impedance adjustment modules 104 in the first energy dissipation unit 1, the second energy dissipation unit 2, and the third energy dissipation unit 3 begin to increase impedance, and ensure that the leakage current leaked to the post insulator 105 remains within 2 mA.
Step A4: The testing proceeds until the DC reference voltages of all resistor modules are measured, and then the voltage-rise test ends.
Step B: A voltage-drop test is performed, including the following specific steps:
Step B1: The control unit 6 controls, in real time, the voltage of the high-capacity DC power supply 5 to drop; meanwhile, the measurement integration module 102 monitors the DC voltage and the leakage current of each resistor module in the first energy dissipation unit 1, the second energy dissipation unit 2, and the third energy dissipation unit 3 in real time.
Step B2: The control unit 6 controls, through the communication module 4, the impedance adjustment module 104 to reduce impedance; in the case that the DC voltage of a resistor module reaches 0.75 times the DC reference voltage, the leakage current of the resistor module is recorded.
Step B3: The control unit 6 continues to control the voltage of the high-capacity DC power supply 5 to drop slowly until the DC reference voltages of all resistor modules are measured, and then the voltage is further reduced to zero, so that the voltage drop process ends and the test is completed.

To illustrate the technical effects of this application more clearly, a specific embodiment of this application is described below.

It is assumed that the first energy dissipation unit 1 includes a first resistor module 101 and a second resistor module 103, referred to as resistor A and resistor D respectively; two resistor modules of the second energy dissipation unit 2, from the high-voltage end downward, are resistors B and E; two resistor modules of the third energy dissipation unit 3, from the high-voltage end downward, are resistor C and resistor F; and the DC reference voltages of resistors A, B, C, D, E, and F are denoted as U_{ref1}, U_{ref2}, U_{ref3}, U_{ref4}, U_{ref5}, and U_{ref6}, respectively, satisfying: U_{ref4}<U_{ref1}<U_{ref5}<U_{ref2}<U_{ref6}<U_{ref3}.

It is assumed that the measurement integration modules 102 at the bottoms of resistors A, B, C, D, E, and F are measurement module A, measurement module B, measurement module C, measurement module D, measurement module E, and measurement module F, respectively.

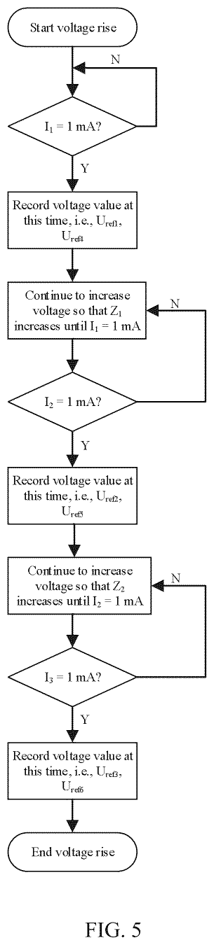

It is assumed that the impedance adjustment modules 104 inside the first energy dissipation unit 1, the second energy dissipation unit 2, and the third energy dissipation unit 3 are regulation module A, regulation module B, and regulation module C, respectively.
(1) Voltage-rise test: As shown in FIG. 5, the control unit 6 controls, in real time, the voltage of the high-capacity DC power supply 5 to rise; meanwhile, the measurement integration module 102 monitors the DC voltage and the leakage current of each resistor module in the first energy dissipation unit 1, the second energy dissipation unit 2, and the third energy dissipation unit 3 in real time, and outputs the DC voltage and the leakage current to the control unit 6 in real time.

When the leakage currents of the resistor A and the resistor D first reach 1 mA, the leakage current and the DC voltage of the measurement module A and the measurement module D are read separately. Subsequently, the control unit 6 calculates the DC reference voltages U_{ref1} and U_{ref4} of the resistor A and the resistor D, and then the voltage is further increased. At this time, the impedance Z₁ of the regulation module A begins to increase. In addition, the leakage currents I₁ of the resistor A and the resistor D are ensured to keep within 2 mA to avoid overcurrent of the high-capacity DC power supply 5. When the leakage currents of the resistor B and the resistor E reach 1 mA, the leakage current and the DC voltage measured by the measurement module B and the measurement module E are read. Subsequently, the control unit 6 calculates the DC reference voltages U_{ref2} and U_{ref5} of the resistor B and the resistor E.

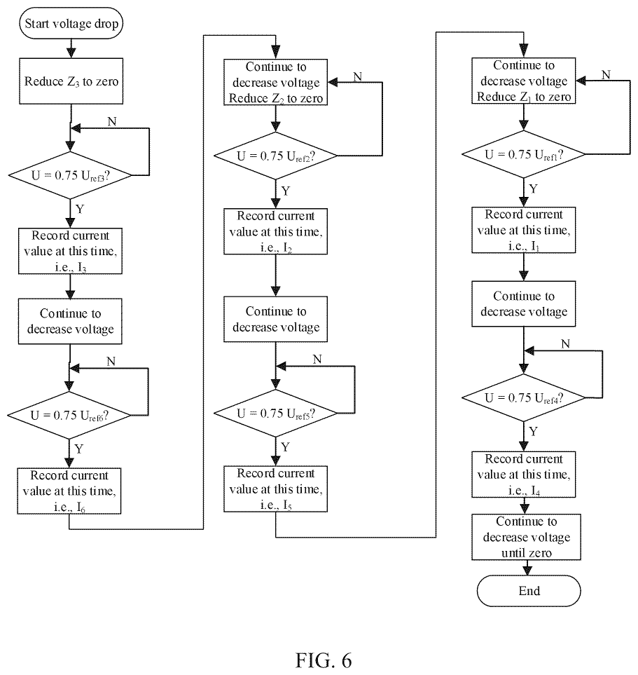

The voltage continues to increase slowly. At this time, the impedance Z₂ of the regulation module B begins to increase. In addition, the leakage currents I₂ of the resistor B and the resistor E are ensured to keep within 2 mA to avoid overcurrent of the high-capacity DC power supply 5. When the leakage currents of the resistor C and the resistor F reach 1 mA, the leakage current and the DC voltage measured by the measurement module C and the measurement module F are read. Subsequently, the control unit 6 calculates the DC reference voltages Uref3 and Urefe of the resistor C and the resistor F.
(2) Voltage-drop test: As shown in FIG. 6, the control unit 6 controls, in real time, the voltage of the high-capacity DC power supply 5 to drop; meanwhile, the measurement integration module 102 monitors the DC voltage and the leakage current of each resistor module in the first energy dissipation unit 1, the second energy dissipation unit 2, and the third energy dissipation unit 3 in real time. When the leakage currents detected by the measurement module A and the measurement module D are less than 1 mA, the impedances Z₁, Z₂ and Z₃ of the regulation module A, the regulation module B, and the regulation module C begin to decrease synchronously. The decrease speed of the impedances is proportional to the drop speed of the voltage of the high-capacity DC power supply 5, and the ratio thereof is greater than 1.

The voltage continues to decrease. When the DC voltage of the resistor C first reaches 0.75 times U_{ref3}, the leakage current I₃ measured by the measurement module C is recorded. At the same time, the impedance Z₃ of the regulation module C has been reduced to zero, without affecting the measurement precision of the resistor C and the resistor F. The voltage continues to decrease slowly. When the DC voltage of the resistor F reaches 0.75 times U_{ref6}, the leakage current I₆ measured by the measurement module F is recorded.

The voltage continues to decrease slowly. When the DC voltage of the resistor B reaches 0.75 times U_{ref2}, the leakage current I₂ measured by the measurement module B is recorded. At the same time, the impedance Z₂ of the regulation module B has been reduced to zero, without affecting the measurement precision of the resistor B and the resistor E. The voltage continues to decrease slowly. When the DC voltage of the resistor E reaches 0.75 times U_{ref5}, the leakage current I₅ measured by the measurement module E is recorded.

The voltage continues to decrease slowly. When the DC voltage of the resistor A reaches 0.75 times U_{ref1}, the leakage current I₁ measured by the measurement module A is recorded. At the same time, the impedance Z₁ of the regulation module A has been reduced to zero, without affecting the measurement precision of the resistor A and the resistor D. The voltage continues to decrease slowly. When the DC voltage of the resistor D reaches 0.75 times U_{ref4}, the leakage current I₄ measured by the measurement module D is recorded, and the voltage drop process ends.

In summary, this application enables testing of all parallel-connected energy dissipation units inside the energy dissipation device through just a single wiring operation, and enables precise measurement of the DC reference voltage and the leakage current of each resistor module in each energy dissipation unit. This application is suitable for DC testing for an energy dissipation device that contains a large number of parallel-connected energy dissipation units, and can perform an overall test for the energy dissipation device containing a plurality of energy dissipation units connected in parallel, thereby significantly reducing the test workload and ensuring reliability of test results.

All the electronic components used herein are universal standard components or the components well-known to a person skilled in the art. The structures and principles of the components can be learned by a person skilled in the art through a technical manual or by using a conventional experimental method.

The foregoing illustrates and describes basic principles, main features, and advantages of the present disclosure. A person skilled in the art understands that the present disclosure is not limited by the above embodiments. The embodiments and the specification only describe the principles of the present disclosure. All variations and improvements made to the present disclosure without departing from the principles and scope of the present disclosure shall fall within the scope of the claims of the present disclosure. The scope of protection of this application is subject to the appended claims and equivalents thereof.

What is claimed is:

1. A testing device for an energy dissipation device in a power transmission system, comprising a high-capacity DC power supply, a first energy dissipation unit, a second energy dissipation unit, a third energy dissipation unit, a communication module, and a control unit, wherein the high-capacity DC power supply is connected to high-voltage terminals of the first energy dissipation unit, the second energy dissipation unit, and the third energy dissipation unit; the first energy dissipation unit, the second energy dissipation unit, and the third energy dissipation unit are connected to each other in parallel; and low-voltage terminals of the first energy dissipation unit, the second energy dissipation unit, and the third energy dissipation unit are all grounded; and
the communication module is disposed within 10 meters of the first energy dissipation unit, the second energy dissipation unit, and the third energy dissipation unit; the communication module is configured to coordinate with the control unit to form a local area network near the first energy dissipation unit, the second energy dissipation unit, and the third energy dissipation unit for measurement and control communication, and to perform control and data reception inside the first energy dissipation unit, the second energy dissipation unit, and the third energy dissipation unit;
the first energy dissipation unit comprises a first resistor module and a second resistor module; a high-voltage terminal of the first resistor module is connected to the high-capacity DC power supply; a low-voltage terminal of the first resistor module is connected to a high-voltage terminal of the second resistor module; a measurement integration module is mounted on outer walls of bottom surfaces of the first resistor module and the second resistor module; a ground terminal of the second resistor module is grounded through a post insulator; and an impedance adjustment module is connected in series between the second resistor module and the post insulator;
a number of the measurement integration modules is two, each measurement integration module is provided with an opening, and is directly fitted onto the outer walls of the bottom surfaces of the first resistor module and the second resistor module separately; and the measurement integration module is made of a DC current sensor and a DC voltage sensor that are Hall-effect-based, and is configured to measure current and voltage in real time;
the impedance adjustment module is configured to automatically adjust a grounding impedance of the second resistor module and make a leakage current of the second resistor module not greater than 2 mA; a precision measurement resistor, a filtering voltage divider, an AD sampler, a high-voltage variable-impedance device, a fine-tuning mechanism, a DSP, and a wireless communicator are disposed inside the impedance adjustment module; the precision measurement resistor is configured to measure voltage and output voltage data to the filtering voltage divider; the filtering voltage divider is configured to filter and scale a voltage signal to obtain a voltage value and a leakage current value, and then output the values to the AD sampler; the AD sampler is configured to convert the voltage value and the leakage current value into digital values and output the digital values to the DSP; the DSP is configured to send a signal to the fine-tuning mechanism after calculation and comparison so that the fine-tuning mechanism adjusts a resistance value; and the wireless communicator is configured to establish a wireless communication connection with the communication module.

2-4. (canceled)

5. The testing device for the energy dissipation device in the power transmission system according to claim 1, wherein the impedance adjustment module and the measurement integration module are wirelessly connected to the control unit by the communication module through wireless data communication; the communication module, the impedance adjustment module, and the measurement integration module are all equipped with and powered by batteries, and a battery charge level is displayed in real time and wirelessly transmitted to the control unit.

6. The testing device for the energy dissipation device in the power transmission system according to claim 1, wherein the first resistor module and the second resistor module are both made of a resistor column, and the resistor column is made of a zinc oxide material.

7. The testing device for the energy dissipation device in the power transmission system according to claim 1, wherein internal structures of both the second energy dissipation unit and the third energy dissipation unit are identical to an internal structure of the first energy dissipation unit.

8. The testing device for the energy dissipation device in the power transmission system according to claim 1, wherein a number of the first energy dissipation units, a number of the second energy dissipation units, and a number of the third energy dissipation units are plural, and the plurality of first energy dissipation units the plurality of second energy dissipation units, and the plurality of third energy dissipation units are all connected in parallel to the high-capacity DC power supply.

9. A testing method applicable to the testing device for the energy dissipation device in the power transmission system according to claim 1, wherein the testing method comprises the following steps:
step A: a voltage-rise test is performed, comprising the following specific steps:
step A1: the control unit controls, in real time, a voltage of the high-capacity DC power supply to rise; meanwhile, the measurement integration module monitors a DC voltage and a leakage current of each resistor module in the first energy dissipation unit, the second energy dissipation unit, and the third energy dissipation unit in real time, and outputs the DC voltage and the leakage current to the control unit in real time;
step A2: in the case that the leakage current of a resistor module reaches 1 mA, a DC reference voltage of the resistor module is recorded;
step A3: the control unit continues to control the voltage of the high-capacity DC power supply to rise slowly; meanwhile, the impedance adjustment modules in the first energy dissipation unit, the second energy dissipation unit, and the third energy dissipation unit begin to increase impedance, and ensure that the leakage current leaked to the post insulator remains within 2 mA;
step A4: the testing proceeds until the DC reference voltages of all resistor modules are measured, and then the voltage-rise test ends;
step B: a voltage-drop test is performed, comprising the following specific steps:
step B1: the control unit controls, in real time, the voltage of the high-capacity DC power supply to drop; meanwhile, the measurement integration module monitors the DC voltage and the leakage current of each resistor module in the first energy dissipation unit, the second energy dissipation unit, and the third energy dissipation unit in real time;
step B2: the control unit controls, through the communication module, the impedance adjustment module to reduce impedance; in the case that the DC voltage of a resistor module reaches 0.75 times the DC reference voltage, the leakage current of the resistor module is recorded; and
step B3: the control unit continues to control the voltage of the high-capacity DC power supply to drop slowly until the DC reference voltages of all resistor modules are measured, and then the voltage is further reduced to zero, so that the voltage drop process ends and the test is completed.

10. The testing method according to claim 9, wherein the impedance adjustment module and the measurement integration module are wirelessly connected to the control unit by the communication module through wireless data communication; the communication module, the impedance adjustment module, and the measurement integration module are all equipped with and powered by batteries, and a battery charge level is displayed in real time and wirelessly transmitted to the control unit.

11. The testing method according to claim 9, wherein the first resistor module and the second resistor module are both made of a resistor column, and the resistor column is made of a zinc oxide material.

12. The testing method according to claim 9, wherein internal structures of both the second energy dissipation unit and the third energy dissipation unit are identical to an internal structure of the first energy dissipation unit.

13. The testing method according to claim 9, wherein a number of the first energy dissipation units, a number of the second energy dissipation units, and a number of the third energy dissipation units are plural, and the plurality of first energy dissipation units, the plurality of second energy dissipation units, and the plurality of third energy dissipation units are all connected in parallel to the high-capacity DC power supply.
